(19) United States
(12) Patent Application Publication
(10) Pub. No.: US 2014/0097021 A1
(43) Pub. Date: Apr. 10, 2014

(54) BUNDLE DIVISION STRUCTURE FOR FLEXIBLE CIRCUIT CABLE

(71) Applicant: ADVANCED FLEXIBLE CIRCUITS CO., LTD., Taoyuan County (TW)

(72) Inventor: KUO-FU SU, Taoyuan County (TW)

(73) Assignee: ADVANCED FLEXIBLE CIRCUITS CO., LTD., Taoyuan County (TW)

(21) Appl. No.: 14/039,112

(22) Filed: Sep. 27, 2013

(30) Foreign Application Priority Data
Oct. 9, 2012 (TW) 101137219

(51) Int. Cl. H05K 9/00

(52) U.S. Cl. CPC H05K 9/00
USPC 174/72 R

(57) ABSTRACT

Disclosed is a bundle division structure for a flexible circuit cable. The flexible circuit cable includes a plurality of conductor units that extends in an extension direction and is collected together to form a clustered structure. The clustered structure defines at least one bundle division section. The bundle division structure includes a bundle division unit, at least a pair of conductor unit receiving slots. The conductor units of the bundle division section are divided into groups that are respectively received in the conductor unit receiving slot. The bundle division unit is coupled to a protection member for protection and positioning purposes.

### BACKGROUND OF THE INVENTION

1. Field of the Invention

The present invention relates to a bundle division structure for a signal transmission cable, and in particular to a bundle division structure for a flexible circuit cable.

2. The Related Arts

Various electronic devices that are currently used require an increasing amount of data to be transmitted through signal lines so that the number of the signal lines used is increase and the frequency used to transmit signals is also raised. Thus, a differential mode of high frequency transmission is commonly adopted to suppress electromagnetic (EMI). For example, such a technology is widely used in USB or LVDS signals to suppress EMI.

After the signal lines have been harnessed, it is a common practice to bundle the signal lines for positioning on the one hand and for protection on the other hand. The conventional way of bundling signal transmission lines is to bundle all the signal transmission lines together and the bundling material used is generally a material for mechanically protecting the lines, such as a length of insulation plastic tape or a piece of conductive fabric, so as to achieve improved resistance against bending or EMI protection that provides high frequency transmission lines with electromagnetic shielding.

Although electromagnetic interference of the surroundings to the signal transmission lines can be suppressed, electromagnetic interference still exists between signal transmission lines because the signal frequencies carried by the signal transmission lines could be different. By bundling all the signal transmission lines in the same bundle, electromagnetic interference among the signal transmission lines may result.

Further, the known technology, when applied to bundle lines, often results in being excessively stiff, making it difficult to flex and move. In addition, stress induced on the signal transmission lines may get concentrated at a specific site. This subjects the signal transmission lines to a severe constrain and may even cause damage of the signal transmission lines. It is thus appreciated that signal transmission lines that are bundled with the conventional ways are generally not fit for use in miniaturized hinge structures that are currently included in for example the fields of mobile phones, digital cameras, and notebook computers.

Further, in applications where a flexible circuit cable is subject to frequency bending and interference by adjacent moving parts around the flexible circuit cable, reliability of signal transmission is often affected by electrostatic discharge induced by machine operations. To effectively and efficiently conduct the static electricity to the ground is thus of importance.

Since the capability of a circuit cable to bear frequency bending and the number of bending that the circuit cable can take are of importance, the conventional arrangements of a circuit cable or wires and protection realized with an outer jacket, although being effective to extend through a bore of a hinge structure, may get readily damaged before the designated number of bending is reached due to stress concentration occurring at corners of the circuit cable caused by folding and rotating and abrasion of the circuit cable with the hinge structure resulting from rotation operations applied by a user during the use of a product including the circuit cable.

The conventional circuit cables are often bundled or wrapped by adhesive tapes, conductive fabrics, and insulation materials, such as PI, to eliminate the potential risk of being incapable of assembling due to being not in an organized form. However, the circuit cable and wires and the protection structures thereof may contact and rub each other due to movement thereof caused by rotation operations and thus causing some of the wires to squeeze each other and get distorted and deformed, leading interruption of transmission conducted through the conductor wires and losing the desired function of transmission. Further, the conventional way of bundling is quite labor-intense in assembling and is hard to meet the requirement for product standardization.

### SUMMARY OF THE INVENTION

Thus, the primary object of the present invention is to provide a bundle division structure for a flexible circuit cable, wherein for interaction between conductor units of a flexible circuit cable and a moving part, a bundle unit is arranged to position the conductor units and to protect the conductors from readily rubbing and thus being damaged due to the interaction thereof with the moving part.

The secondary object of the present invention is to divide conductor units into different bundles according to groups thereof and to set the bundles respectively in a first conductor unit receiving slot and a second conductor unit receiving slot so as to reduce mutual interference occurring between different conductor groups that transmit different electrical signals.

The tertiary object of the present invention is to conduct static electricity generated by rubbing caused by interaction with a moving part in order to reduce electrostatic discharge and to eliminate electromagnetic interference.

The technical solution that the present invention adopts to address the technical issues is that a plurality of conductor units of a flexible circuit cable is set to extend in an extension direction and is collected together to form a clustered structure. The clustered structure defines at least one bundle division section. The conductor units of the bundle division section are divided into a first conductor group and at least one second conductor group, which are respectively received in the first conductor unit receiving slot and the second conductor unit receiving slot of the bundle division unit and respectively extend from the first end of the bundle division unit through the first conductor unit receiving slot and the second conductor unit receiving slot to the second end of the bundle division unit.

In a second embodiment according to the present invention, the outer circumferential surface of the bundle division unit is coupled to a protection member. The protection member comprises a ring structure having a fixed width and is selectively made of a metal material so that static electricity generated by interaction between the protection member and an external moving part can be conducted to the surroundings by the metal material that makes the protection member so as to reduce the electrostatic effect. Further, a grounding wire may be further provided to conduct the static electricity to the surroundings to reduce the electrostatic effect and protect the conductor units, for signal transmission, from being affected by the static electricity generated by interaction thereof with an external moving part.

The protection member can be integrally formed to show a predetermined wrapping pitch, a predetermined helical angle, and a predetermined wrapping diameter and can be set to extend in a wrapping direction to wrap around the bundle division unit. The protection member can be made of a shielding material in order to protect the conductor units from interference of external electromagnetism for signal transmission therethrough.

In a third embodiment according to the present invention, the bundle division structure for the flexible circuit cable further comprises at least one third conductor unit receiving slot and at least one third conductor group. The third conductor group is received in the third conductor unit receiving slot and extends from the first end of the bundle division unit through the third conductor unit receiving slot to the second end of the bundle division unit.

With the technical solution adopted by the present invention, during the interaction between a flexible circuit cable and a moving part, the bundle division unit functions to position and protect the conductor units so that the conductor units are not readily damaged due to rubbing in the interaction thereof with the moving part. Further, the conductor units are divided into groups and separately bundled to reduce mutual interference between different conductor groups that transmit different electrical signals.

Further, static electricity generated due to rubbing in the interaction with a moving part is conducted to the surrounding in order to reduce electrostatic discharge and suppress electromagnetic interference. Thus, during transmission of high frequency differential mode signals with an electronic device, errors and distortions of transmitted signals can be avoided.

### BRIEF DESCRIPTION OF THE DRAWINGS

The present invention will be apparent to those skilled in the art by reading the following description of preferred embodiments of the present invention, with reference to the attached drawings, in which:

FIG. 1 is a schematic view showing the structure of a bundle division structure for a flexible circuit cable according to the present invention;

FIG. 2 is a schematic view showing the structure of a flexible circuit cable;

FIG. 3 is a partial enlarged view of the flexible circuit cable;

FIG. 4 is a schematic view showing the structure of a first embodiment of the present invention;

FIG. 5 is a schematic view showing a structure that a second end of the flexible circuit cable of the first embodiment of the present invention is connected to a first separated connection section and a second separated connection section;

FIG. 6 is a schematic view showing a first example of the conductor units of the flexible circuit cable received in the first conductor unit receiving slot and the second conductor unit receiving slot;

FIG. 7 is a schematic view showing a second example of the conductor units of the flexible circuit cable received in the first conductor unit receiving slot and the second conductor unit receiving slot;

FIG. 8 is a schematic view showing a third example of the conductor units of the flexible circuit cable received in the first conductor unit receiving slot and the second conductor unit receiving slot;

FIG. 9 is a schematic view showing a fourth example of the conductor units of the flexible circuit cable received in the first conductor unit receiving slot and the second conductor unit receiving slot;

FIG. 10 is a schematic view illustrating a first example of a structure that a bundle division unit is combined with a protection member according to a second embodiment of the present invention;

FIG. 11 is a schematic view illustrating a second example of a structure that a bundle division unit is combined with a protection member according to the second embodiment of the present invention;

FIG. 12 is a cross-sectional view taken along line 12-12 of FIG. 11;

FIG. 13 is a partial enlarged view of FIG. 12 showing a first example;

FIG. 14 is a partial enlarged view of FIG. 12 showing a second example; and

FIG. 15 is a schematic view showing the structure of a third embodiment according to the present invention.

### DETAILED DESCRIPTION OF THE PREFERRED EMBODIMENTS

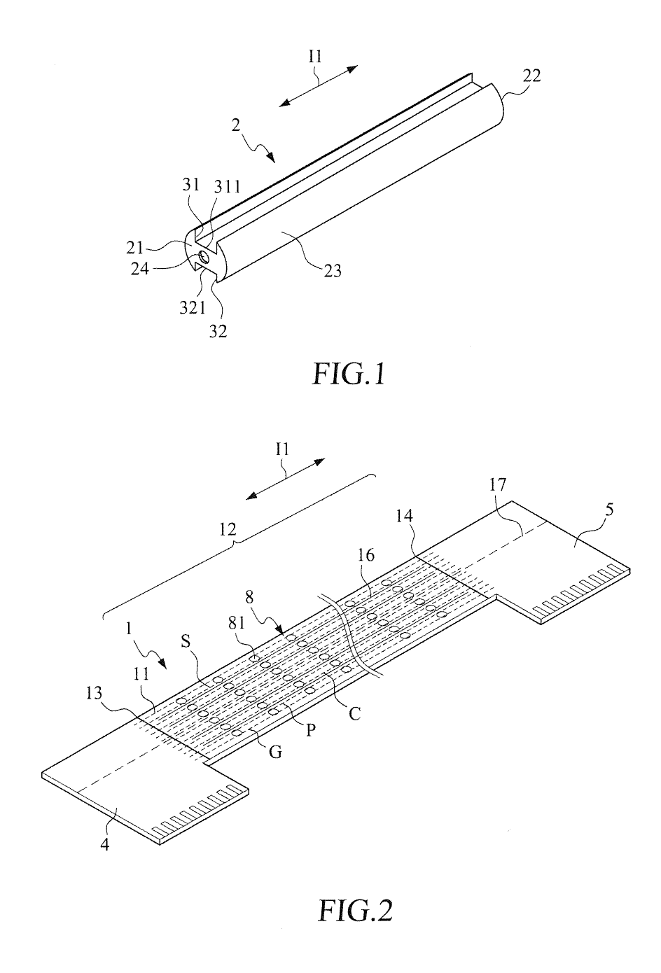

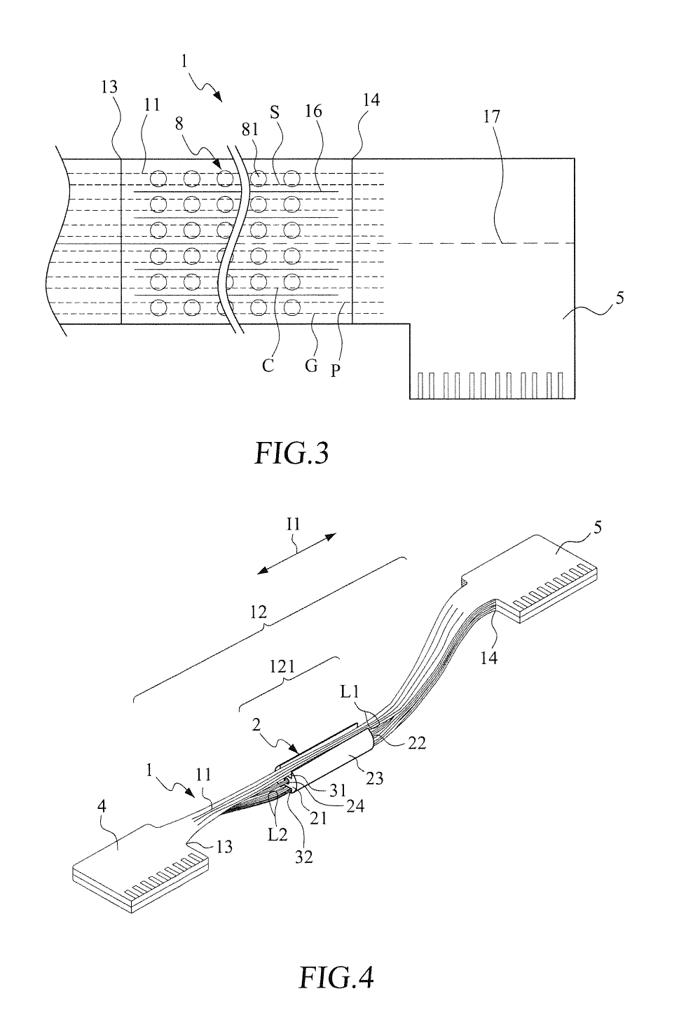

With reference to the drawings and in particular to FIGS. 1-4, FIG. 1 is a schematic view showing the structure of a bundle division structure for a flexible circuit cable according to the present invention; FIG. 2 is a schematic view showing the structure of a flexible circuit cable; FIG. 3 is a partial enlarged view of the flexible circuit cable; and FIG. 4 is a schematic view showing the structure of a first embodiment of the present invention. As shown in the drawings, a flexible circuit cable 1 used in a bundle division structure according to the present invention comprises a plurality of conductor units 11, which extends in an extension direction I1 and is collected together to form a clustered structure 12. The clustered structure defines at least one bundle division section 121.

The bundle division structure comprises a bundle division unit 2, a first conductor unit receiving slot 31, and at least one second conductor unit receiving slot 32. The bundle division unit 2 comprises a first end 21 and a second end 22 and extends in the extension direction 1 by a predetermined length and forms an outer circumferential surface 23 between the first end 21 and the second end 22.

The first conductor unit receiving slot 31 has a bottom 311 that is lower than an outer circumferential surface 23 of the bundle division unit 2 by a height H and extends in the extension direction I1 from the first end 21 of the bundle division unit 2 to the second end 22.

The second conductor unit receiving slot 32 is spaced from the first conductor unit receiving slot 31. The second conductor unit receiving slot 32 has a bottom 321 that is lower than the outer circumferential surface 23 of the bundle division unit 2 by a height H and extends in the extension direction 11 from the first end 21 of the bundle division unit 2 to the second end 22.

The conductor units 11 of the bundle division section 121 of the flexible circuit cable 1 are divided into a first conductor group L1 and at least one second conductor group L2, which are respectively received in the first conductor unit receiving slot 31 and the second conductor unit receiving slot 32 and extend respectively from the first end 21 of the bundle division unit 2 through the first conductor unit receiving slot 31 and the second conductor unit receiving slot 32 to the second end 22 of the bundle division unit 2.

The first end 13 of the flexible circuit cable 1 is connected to a first integrated connection section 4 and the second end 14 of the flexible circuit cable 1 is connected to a second integrated connection section 5. The first integrated connection section 4 and the second integrated connection section 5 may ach comprise one of an inserting terminal, an insertion slot, a connector, a soldering terminal, an electronic device, a surface-mounted device.

The plurality of conductor units 11 of the flexible circuit cable 1 includes a plurality of differential mode signal transmission lines S, at least one grounding line G, and at least one power line P. The flexible circuit cable 1 comprises a flexible substrate 15 that is subject to slitting in the extension direction 11 to form a plurality of slit lines 16 for forming the clustered structure 12. Further, the flexible substrate 15 of the flexible circuit cable 1 comprises at least one folding line 17 in the extension direction I1. Further, the conductor units 11 include at least one common mode signal transmission line C.

The bundle division unit 2 further comprises at least one through bore 24, which extends in the extension direction I1 from the first end 21 of the bundle division unit 2 to the second end 22. A fraction of the conductor units 11 is arranged to extend from the first end 21 of the bundle division unit 2 through the through bore 24 to the second end 22 of the bundle division unit 2 and some of the conductor units 11 include at least one grounding line G and at least one power line P. Further, in a practical application, the through bore 24 can selectively omitted according to the needs.

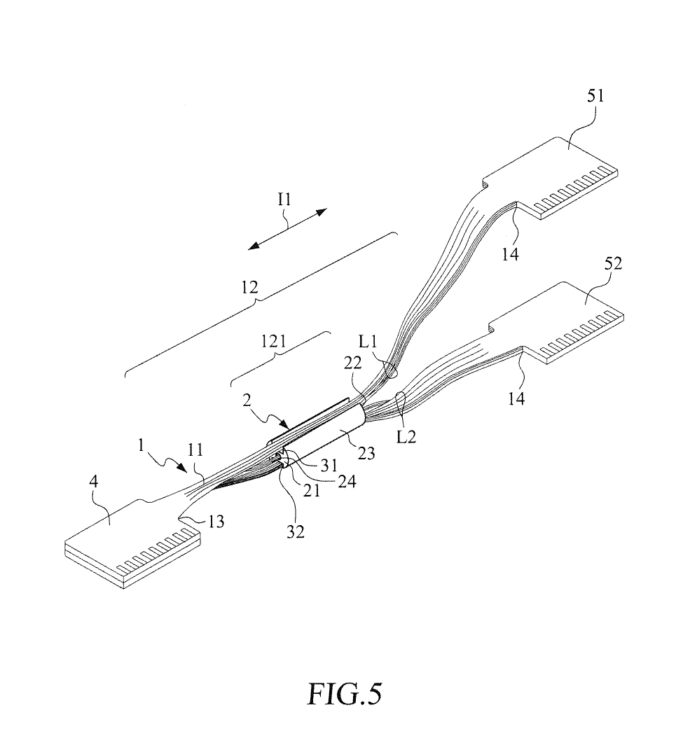

Referring to FIG. 5, a schematic view is given to illustrate a structure that the second end of the flexible circuit cable of the first embodiment of the present invention is connected to a first separated connection section and a second separated connection section. As shown in the drawing, according to the groups of the conductors, the second end 14 of the flexible circuit cable 1 can be connected to both a first separated connection section 51 and a second separated connection section 52. The first integrated connection section 4, the first separated connection section 51, and the second separated connection section 52 may each comprise one of an inserting terminal, an insertion slot, a connector, a soldering terminal, an electronic device, a surface-mounted device.

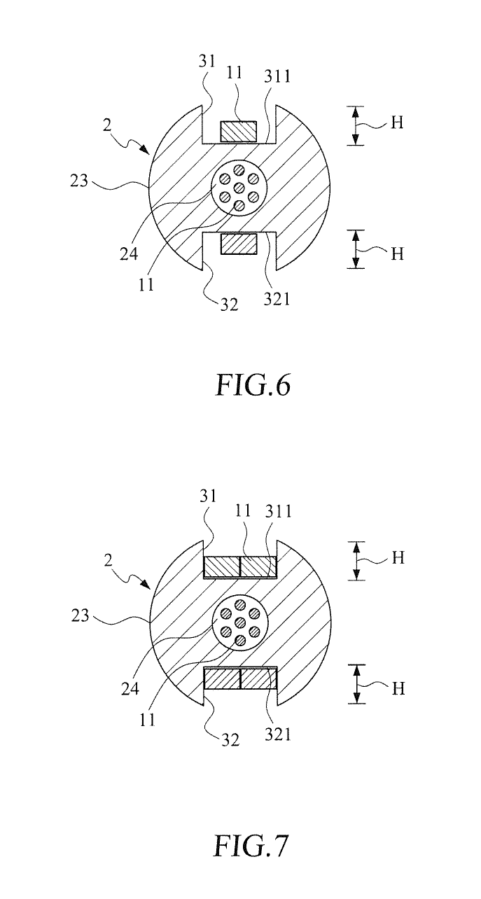

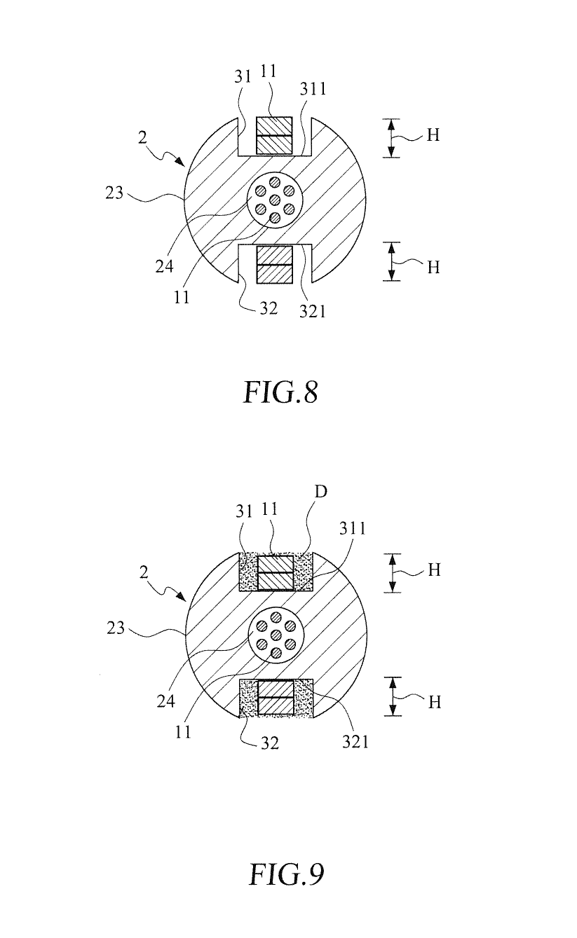

Referring to FIGS. 6-8, FIG. 6 is a schematic view showing a first example of the conductor units of the flexible circuit cable received in the first conductor unit receiving slot and the second conductor unit receiving slot; FIG. 7 is a schematic view showing a second example of the conductor units of the flexible circuit cable received in the first conductor unit receiving slot and the second conductor unit receiving slot; and FIG. 8 is a schematic view showing a third example of the conductor units of the flexible circuit cable received in the first conductor unit receiving slot and the second conductor unit receiving slot. As shown in the drawings, a designer is allowed to set the conductor units 11 in the first conductor unit receiving slot 31 and the second conductor unit receiving slot 32 in various ways according to different needs and circuit designs.

As shown in FIG. 6, in setting the conductor units 11 of the flexible circuit cable 1 in the first conductor unit receiving slot 31 and the second conductor unit receiving slot 32, the designer may select to place a single conductor unit 11 in each of the first conductor unit receiving slot 31 and the second conductor unit receiving slot 32 according to the needs and circuit design, or to alternatively place the conductor units 11 in a juxtaposed manner in each of the first conductor unit receiving slot 31 and the second conductor unit receiving slot 32 (as shown in FIG. 7), or to alternatively place the conductor units 11 in an up-down stacked manner in each of the first conductor unit receiving slot 31 and the second conductor unit receiving slot 32 (as shown in FIG. 8).

Further, in a practical application, the bundle division unit 2 has a cross-section that can be a circle, a rectangle, a polygon, or other geometric shapes according to the needs and is not limited to a circular one.

Referring to FIG. 9, a schematic view is given to illustrate a fourth example of the conductor units of the flexible circuit cable received in the first conductor unit receiving slot and the second conductor unit receiving slot. As shown in the drawing, the conductor units 11 of the first conductor group L1 are set in the first conductor unit receiving slot 31 and the conductor units 11 of the second conductor group L2 are set in the second conductor unit receiving slot 32 and they are respectively fixed by an adhesive material D in the first conductor unit receiving slot 31 and the second conductor unit receiving slot 32. With the application of the adhesive material D, the conductor units 11 of the first conductor group L1 and the conductor units 11 of the second conductor group L2 are respectively positioned and fixed in the first conductor unit receiving slot 31 and the second conductor unit receiving slot 32.

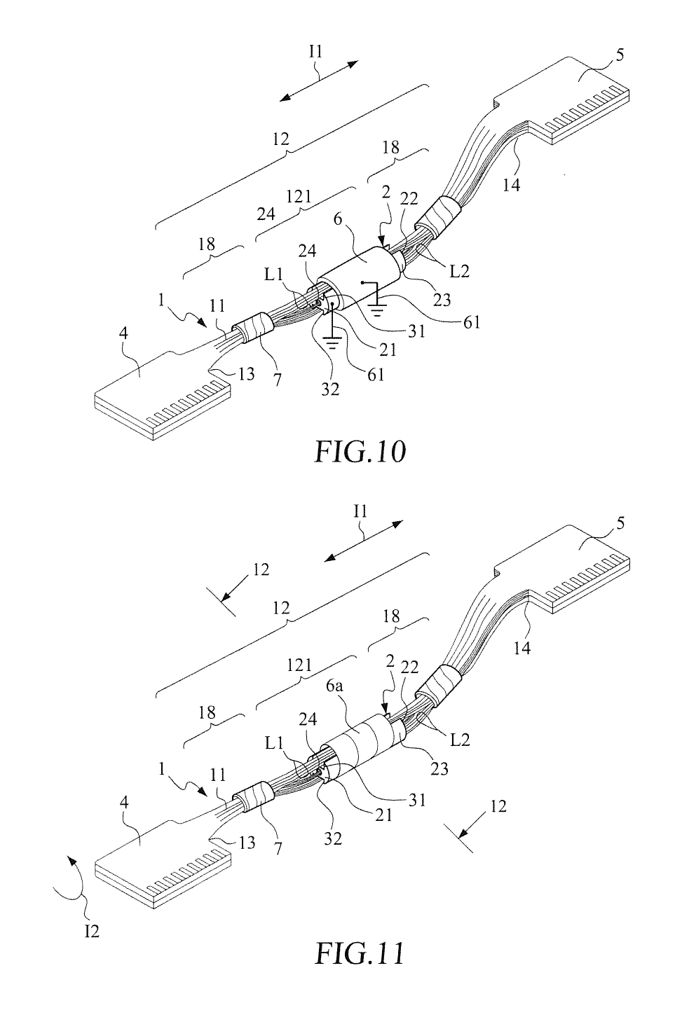

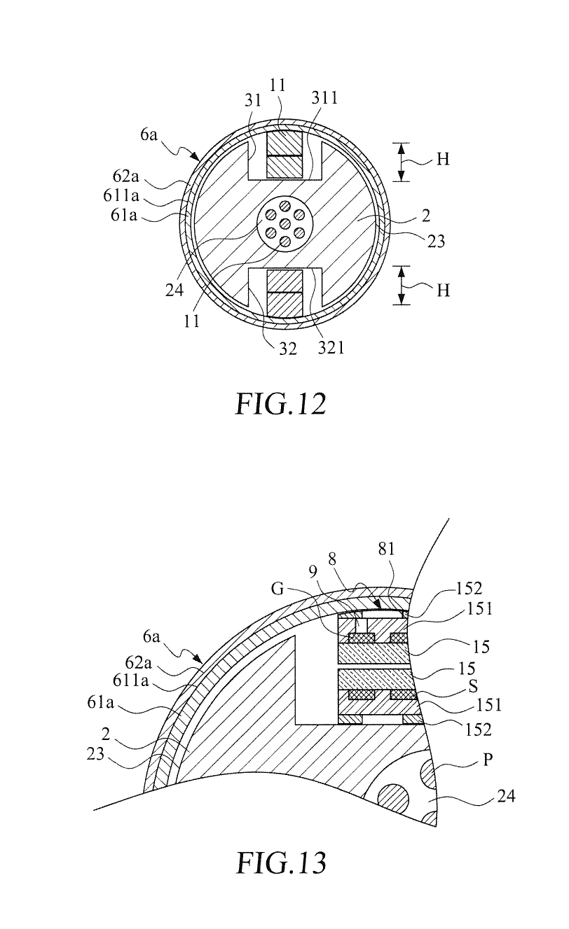

Referring to FIGS. 10-12, FIG. 10 is a schematic view illustrating a first example of a structure that a bundle division unit is combined with a protection member according to a second embodiment of the present invention; FIG. 11 is a schematic view illustrating a second example of a structure that a bundle division unit is combined with a protection member according to the second embodiment of the present invention; and FIG. 12 is a cross-sectional view taken along line 12-12 of FIG. 11. As shown in the drawings, the outer circumferential surface 23 of the bundle division unit 2 is coupled to a protection member 6, 6a.

As shown in FIGS. 10 and 11, the clustered structure 12 of the flexible circuit cable 1 further defines at least one bundled section 18, where the conductor units 11 are wrapped and bundled by a bundling member 7.

The protection member 6 comprises a ring structure having a fixed width and is selectively made of a metal material so that static electricity generated by interaction between the protection member 6 and an external moving part can be conducted to the surroundings by the metal material that makes the protection member 6 so as to reduce the electrostatic effect. Further, a grounding wire 61 may be further provided to conduct the static electricity to the surroundings to reduce the electrostatic effect and protect the conductor units 11, for signal transmission, from being affected by the static electricity generated by interaction thereof with an external moving part.

The protection member 6a can be integrally formed to show a predetermined wrapping pitch, a predetermined helical angle, and a predetermined wrapping diameter and can be set to extend in a wrapping direction 12 to wrap around the bundle division unit 2. The protection member 6a can be made of a shielding material in order to protect the conductor units 11 from interference of external electromagnetism for signal transmission therethrough. Alternatively, the protection member 6a may comprise a ring structure 61a made of a non-shielding material and a shielding layer 62a formed on outer circumferential surface 611a of the ring structure 61a. Further, the protection members 6, 6a may be each made of one of a rigid material and a flexible material.

In a practical application, the protection member 6a is set in the wrapping direction 12 to wrap around the bundle division unit 2 to be, according to the needs, tightly surround the bundle division unit 2 or spaced from the bundle division unit 2 by a gap to allow the protection member 6a to be in a slidable engagement with the conductor units 11 of the flexible circuit cable, whereby the conductor units 11 are allowed to axially slide within the protection member 6a.

Referring to FIG. 13, a partial enlarged view of FIG. 12 showing a first example is given. As shown in the drawing, the flexible substrate 15 of the flexible circuit cable 1 is provided with an insulation layer 151 covering the differential mode signal transmission lines S and a shielding layer 152 formed on the insulation layer 151. The shielding layer 152 is in contact with the bundle division unit 2. The grounding line G is connected through a conductive via hole 9 with the protection member 6a.

The shielding layer 152 forms an impedance control structure 8 (also see FIG. 2). The impedance control structure 8 functions as an impedance control structure for the differential mode signal transmission lines S. In a practical application, the impedance control structure 8 comprises a plurality of openings 81 formed in the shielding layer 152. The openings 81 can be circular, rhombus, or rectangular holes or can be of other geometric shapes.

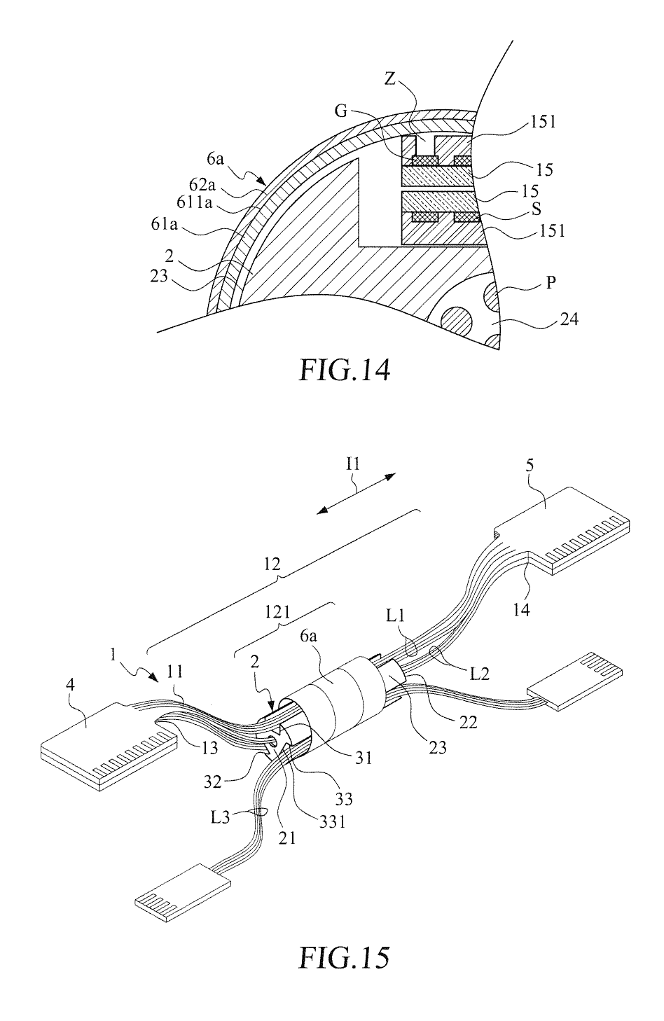

Referring to FIG. 14, a partial enlarged view of FIG. 12 showing a second example is given. As shown in the drawing, the flexible substrate 15 of the flexible circuit cable 1 is provided with an insulation layer 151 covering the differential mode signal transmission lines S. The insulation layer 151 comprises an exposed section Z corresponding to the grounding line G to have the grounding line G exposed and contacting the protection member 6a.

Referring to FIG. 15, a schematic view is given to show the structure of a third embodiment according to the present invention. As shown in the drawing, the bundle division structure for the flexible circuit cable according to the present invention further comprises at least one third conductor unit receiving slot 33 and at least one third conductor group L3.

The third conductor unit receiving slot 33 is spaced from the first conductor unit receiving slot 311. The third conductor unit receiving slot 33 has a bottom 331 lower than the outer circumferential surface 23 of the bundle division unit 2 by a height H and extends in the extension direction I1 from the first end 21 of the bundle division unit 2 to the second end 2.

The third conductor group L3 is received in the third conductor unit receiving slot 33 and extends from the first end 21 of the bundle division unit 2 through the third conductor unit receiving slot 33 to the second end 22 of the bundle division unit 2.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A bundle division structure for a flexible circuit cable, the flexible circuit cable comprising a plurality of conductor units that extends in an extension direction and is collected together to form a clustered structure, the clustered structure defining at least one bundle division section, the bundle division structure comprising:
a bundle division unit, which comprises a first end and a second end and extends in the extension direction by a predetermined length and forms an outer circumferential surface between the first end and the second end;
a first conductor unit receiving slot, which has a bottom lower than an outer circumferential surface of the bundle division unit by a height and extends in the extension direction from the first end of the bundle division unit to the second end; and
at least one second conductor unit receiving slot, which is spaced from the first conductor unit receiving slot, the second conductor unit receiving slot having a bottom lower than the outer circumferential surface of the bundle division unit by a height and extends in the extension direction from the first end of the bundle division unit to the second end;
wherein the conductor units of the bundle division section of the flexible circuit cable are divided into a first conductor group and at least one second conductor group, which are respectively received in the first conductor unit receiving slot and the second conductor unit receiving slot and extend respectively from the first end of the bundle division unit through the first conductor unit receiving slot and the second conductor unit receiving slot to the second end of the bundle division unit.

2. The bundle division structure as claimed in claim 1, wherein the outer circumferential surface of the bundle division unit is coupled to a protection member.

3. The bundle division structure as claimed in claim 2, wherein the protection member is integrally formed to show a predetermined wrapping pitch, a predetermined helical angle, and a predetermined wrapping diameter and is set to extend in a wrapping direction to wrap around the bundle division unit.

4. The bundle division structure as claimed in claim 2, wherein the protection member comprises a ring structure having a fixed width.

5. The bundle division structure as claimed in claim 2, wherein the protection member is made of a metal material.

6. The bundle division structure as claimed in claim 2, wherein the protection member comprises a ring structure made of a non-shielding material and a shielding layer formed on outer circumferential surface of the ring structure.

7. The bundle division structure as claimed in claim 1, wherein the flexible circuit cable has a first end connected to a first integrated connection section, a second end of the flexible circuit cable being connected to a second integrated connection section.

8. The bundle division structure as claimed in claim 1, wherein the flexible circuit cable has a first end connected to a first integrated connection section, a second end of the flexible circuit cable being connected to a first separated connection section and a second separated connection section according to the conductor groups.

9. The bundle division structure as claimed in claim 1, wherein the flexible circuit cable comprises a flexible substrate and a plurality of signal transmission lines formed on the flexible substrate, the flexible substrate being slit in the extension direction to form a plurality of slit lines so as to form the clustered structure.

10. The bundle division structure as claimed in claim 9, wherein the flexible substrate comprises at least one folding line formed to extend in the extension direction.

11. The bundle division structure as claimed in claim 9, wherein the flexible substrate comprises an insulation layer covering the signal transmission lines and a shielding layer formed on the insulation layer.

12. The bundle division structure as claimed in claim 11, wherein the shielding layer is in contact with the bundle division unit.

13. The bundle division structure as claimed in claim 11, wherein the signal transmission lines comprise differential mode signal transmission lines and the shielding layer forms an impedance control structure.

14. The bundle division structure as claimed in claim 1, wherein the conductor units include at least one grounding line.

15. The bundle division structure as claimed in claim 1, wherein the clustered structure defines at least one bundled section, a bundling member bundling the conductor units at the bundled section.

16. The bundle division structure as claimed in claim 1 further comprising:
at least one third conductor unit receiving slot, which is spaced from the first conductor unit receiving slot, the third conductor unit receiving slot having a bottom lower than the outer circumferential surface of the bundle division unit by a height and extending in the extension direction from the first end of the bundle division unit to the second end; and
at least one third conductor group, which is received in the third conductor unit receiving slot and extends from the first end of the bundle division unit through the third conductor unit receiving slot to the second end of the bundle division unit.

17. The bundle division structure as claimed in claim 1, wherein the bundle division unit further comprises at least one through bore, the through bore extending in the extension direction from the first end of the bundle division unit to the second end.

18. The bundle division structure as claimed in claim 1, wherein the conductor units of the first conductor group are arranged in such a way that at least two of the conductor units are received in the first conductor unit receiving slot in one of a juxtaposed manner and a up-down stacked manner and the conductor units of the second conductor group are arranged in such a way that at least two of the conductor units are received in the second conductor unit receiving slot in one of a juxtaposed manner and a up-down stacked manner.

19. The bundle division structure as claimed in claim 1, wherein the conductor units of the first conductor group that are received in the first conductor unit receiving slot and the conductor units of the second conductor group that are received in the second conductor unit receiving slot are fixed by an adhesive material in the first conductor unit receiving slot and the second conductor unit receiving slot.

20. The bundle division structure as claimed in claim 1, wherein the bundle division unit has a cross-section that is one of a circle, a rectangle, and a polygon.
